(19) United States
(12) Patent Application Publication
(10) Pub. No.: US 2026/0060044 A1
(43) Pub. Date: Feb. 26, 2026

(54) FILM FORMATION METHOD AND ARTICLE MANUFACTURING METHOD

(71) Applicant: CANON KABUSHIKI KAISHA, Tokyo (JP)

(72) Inventors: SATORU JIMBO, Tokyo (JP); HIROSHI KUROSAWA, Chiba (JP)

(21) Appl. No.: 19/298,548

(22) Filed: Aug. 13, 2025

(30) Foreign Application Priority Data
Aug. 23, 2024 (JP) 2024-143356

(51) Int. Cl. H01L 21/027; H01L 23/544

(52) U.S. Cl. CPC H01L 21/0273; H01L 23/544; H01L 2223/54426

(57) ABSTRACT

A film formation method of forming a planarized film on a substrate, includes bringing a circular region of a mold, in which the planarized film should be formed, into contact with a composition on the substrate, performing alignment between the substrate and the mold in a state in which the composition and the mold are in contact, and applying curing energy to the composition after the performing alignment, wherein after a part of the mold contacts the composition in the bringing the mold into contact with the composition, the performing alignment is started before an entire surface of the circular region of the mold contacts the composition.

### BACKGROUND

### Field of the Technology The present disclosure relates to a film formation method and an article manufacturing method.

### Description of the Related Art

A device manufacturing step includes a step of etching a substrate with a pattern formed thereon. Because of this step, if the residual film thickness of the pattern formed on the substrate is not even over all of the substrate surface, the shape (for example, a line width) of a pattern obtained by removing the residual film may be uneven. For this reason, there is needed a technique of planarizing the substrate by making the residual film thickness even. Conventionally, to planarize steps on a substrate, a technique of forming a coating film using an existing coater or the like has been proposed. However, sufficient planarization performance cannot be obtained for a nanoscale step.

In recent years, an apparatus that planarizes a substrate using an imprint technique has been proposed. In this apparatus, a composition on a substrate is molded using a mold (also called a plane template or a superstrate) without a pattern, and the molded composition is cured by, for example, UV exposure, thereby forming a planarized film.

In the apparatus that forms a composition using the imprint technique, since a composition in an amount according to steps on a substrate is supplied onto the substrate, the planarization accuracy is expected to be improved as compared to existing methods (for example, Japanese Patent Laid-Open No. 2016-219679).

Recently, proposals have been made, in which a pattern for improving filling properties of a composition is formed on a mold for a planarization apparatus, or a taper is provided at an end portion of a mold to prevent a composition from extruding. In this case, the alignment accuracy of the mold is required to be improved.

### SUMMARY

The present disclosure provides a technique advantageous in improving the alignment accuracy of a mold used to form a planarized film.

The present disclosure in its one aspect provides a film formation method of forming a planarized film on a substrate, including bringing a circular region of a mold, in which the planarized film should be formed, into contact with a composition on the substrate, performing alignment between the substrate and the mold in a state in which the composition and the mold are in contact, and applying curing energy to the composition after the performing alignment, wherein after a part of the mold contacts the composition in the bringing the mold into contact with the composition, the performing alignment is started before an entire surface of the circular region of the mold contacts the composition.

Features of the present disclosure will become apparent from the following description of embodiments with reference to the attached drawings. The following description of embodiments are described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIGS. 1A to 1D are views for explaining the outline of planarization processing;

FIG. 2 is a view showing the configuration of a film formation apparatus;

FIG. 3 is a view showing an example of the configuration of a controller;

FIG. 4 is a flowchart of a film formation method;

FIG. 5 is a view showing a process of forming a liquid film;

FIGS. 6A and 6B are views showing examples of the arrangements of alignment marks;

FIG. 7 is a flowchart of an alignment step;

FIG. 8 is a flowchart showing a detailed example of a formation step;

FIGS. 9A to 9E are views showing the operation of a film formation unit in the formation step;

FIGS. 10A to 10E are views showing the operation of a film formation unit in a formation step;

FIGS. 11A to 11F are views showing state transition on a substrate in the formation step;

FIGS. 12A to 12H are views showing state transition on a substrate in a formation step; and

FIG. 13 is a view exemplarily showing the structure of a mold.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

### First Embodiment

A film formation apparatus according to the embodiment will now be described. The film formation apparatus is used to manufacture a device such as a semiconductor device as an article, and the film formation apparatus arranges a composition in an uncured state on a substrate and molds the arranged composition using a mold, thereby forming a film of the composition on the substrate. In this embodiment, the film formation apparatus can be a film formation apparatus employing a photocuring method. Since the photocuring method is employed, the composition is a photocurable moldable material.

On the premise of a mass production apparatus for semiconductor devices or the like, there are known a pattern transfer method and apparatus to which imprint lithography employing the photocuring method is applied. The imprint method using the photocuring method is substantially performed in the following way. First, a composition to be cured by ultraviolet rays is supplied, by a supply mechanism (dispenser) using an inkjet nozzle, to a shot region that is an imprint target on a substrate. After that, a mold with a device pattern drawn thereon is brought into contact with the composition. If the composition sufficiently permeates into the pattern of the mold, the composition is cured by irradiating it with light (ultraviolet rays (UV)). After that, the mold is separated from the composition. Thus, a fine pattern with excellent line width variations can be formed on the wafer.

In an EUV photolithography process, as the NA become higher, the depth of focus (DOF) of a projected image of a fine circuit pattern recently becomes shallower. In recent examples, the DOF allowed for an EUV lithography apparatus with NA=0.33 is said to be 300 to 110 nm (depending on the illumination mode). The DOF allowed for an EUV lithography apparatus with NA=0.55 is said to be 160 to 40 nm (depending on the illumination mode). However, it is found that in a conventional method of applying an SOC film using a spin coater, it is difficult to obtain sufficient surface planarization performance within such an allowable range. Particularly in spin coating, a layer having an even film thickness is formed on a wafer by the viscosity of an SOC coating agent dropped on the substrate (wafer) and a centrifugal force generated by spin. Hence, if a portion where the change of the wiring density of an underlying pattern of the process wafer is 5 μm or more exists at a long period, a boundary at which the wiring density changes directly appears as relief on the SOC film surface.

Recently, a planarization method using the above-described imprint technique has been examined. In this method, a superstrate that is a mold without a pattern is pressed against a composition that is supplied in a liquid state onto a substrate, and when the composition spreads throughout, the composition is cured by UV exposure, and the superstrate is then separated. Note that the term “imprint” is often used in a concept of transferring a pattern formed on a mold by bringing it into contact with a composition on a substrate, but no pattern is drawn on the superstrate in planarization processing.

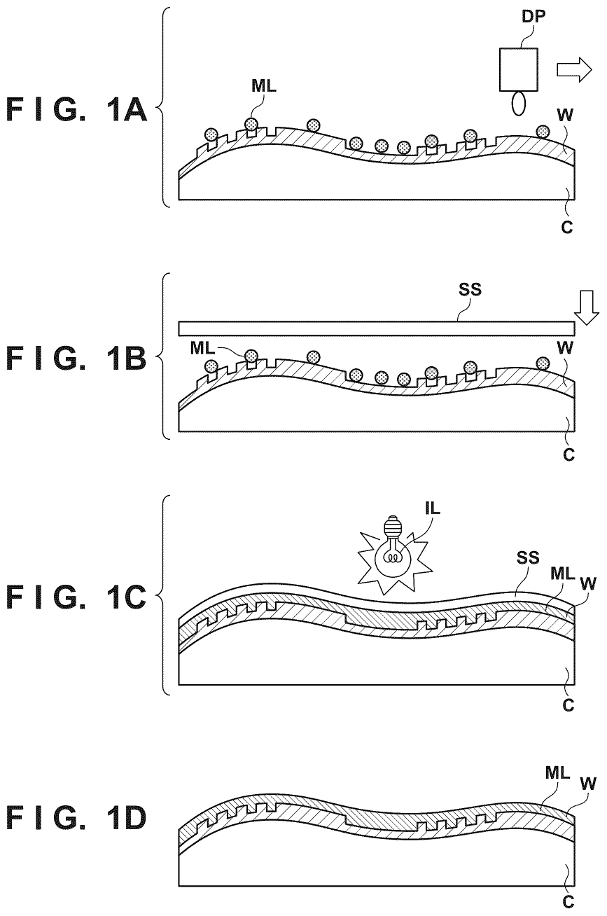

The outline of planarization processing using an imprint technique by a photocuring method will be described with reference to FIGS. 1A to 1D. In the planarization processing using the imprint technique by the photocuring method, a substrate can be planarized by a supply step shown in FIG. 1A, a contact step shown in FIG. 1B, a curing step shown in FIG. 1C, and a mold release step shown in FIG. 1D. In FIGS. 1A to 1D, a circuit pattern is already formed on the surface of a substrate W chucked by a substrate chuck C, and there can exist unevenness of, for example, about 80 to 100 nm derived from the pattern. The requirement of planarization according to this embodiment is to planarize the surface unevenness derived from the pattern.

In the supply step shown in FIG. 1A, a composition ML that is a planarization material is supplied from a dispenser DP to the surface of the substrate W chucked by the substrate chuck C. The dispenser DP can be arranged on a bridge (not shown) suspended on a base also serving as a Z-direction guide for a substrate stage that holds the substrate chuck C. When the substrate W chucked by the substrate chuck C is scan-driven once or a plurality of times under the dispenser DP, the composition ML is supplied to the whole surface of the substrate. The dispenser DP can be a jetting module that supplies the composition ML in a state of droplets. The dispenser DP can supply the composition ML while giving a distribution to the supply amount thereof in accordance with the arrangement of concave-convex patterns or the like formed on the surface of the substrate W. More specifically, the composition ML can be supplied such that the droplet density becomes high in a portion where the ratio of concave portions of the pattern is high on the substrate surface and the droplet density becomes low in a portion where the ratio is low. Hence, when supplying the composition ML by the dispenser DP, substrate alignment measurement can be performed to make the position of the pattern formed on the substrate W in advance match the position of the density pattern of the composition ML to be supplied. Note that supply (application) of the composition ML may be done by a spin coating method.

In the contact step shown in FIG. 1B, a superstrate SS (also called a “plane template”) that is a mold having an outer diameter substantially equal to or more than that of the substrate W and having a flat surface without a pattern formed thereon contacts the composition ML, and the superstrate SS is pressed against the whole region of the surface of the substrate W. The composition ML thus spreads in a layer form (to be referred to as “filling” or “spread” hereinafter).

In the curing step shown in FIG. 1C, in a state in which the superstrate SS is in contact with the composition ML on the substrate W, the whole region of the surface of the substrate W is irradiated with ultraviolet rays from a light source IL at once (or by repeating partial exposure). The composition ML spread in a layer form is thus cured.

In the mold release step shown in FIG. 1D, the superstrate SS is separated from the cured composition ML on the substrate W. The surface unevenness of the substrate W derived from the pattern is thus planarized. Note that here, the process does not aim at correcting flatness of a component of a low spatial frequency with which the profile of the entire substrate is distorted with respect to an absolute plane. For such a component, a non-plane component is compensated for in a subsequent pattern formation step by focus follow-up control of an exposure apparatus.

The planarization processing using the imprint technique is a technique of supplying a composition in accordance with steps on a substrate, bringing a flat and thin member called a superstrate into contact with the supplied composition, and curing the composition, thereby performing planarization in nano order.

Hence, in an example, the film formation apparatus can be a planarization apparatus using the imprint technique. Hereinafter, a detailed example will be described assuming that the film formation apparatus is a planarization apparatus.

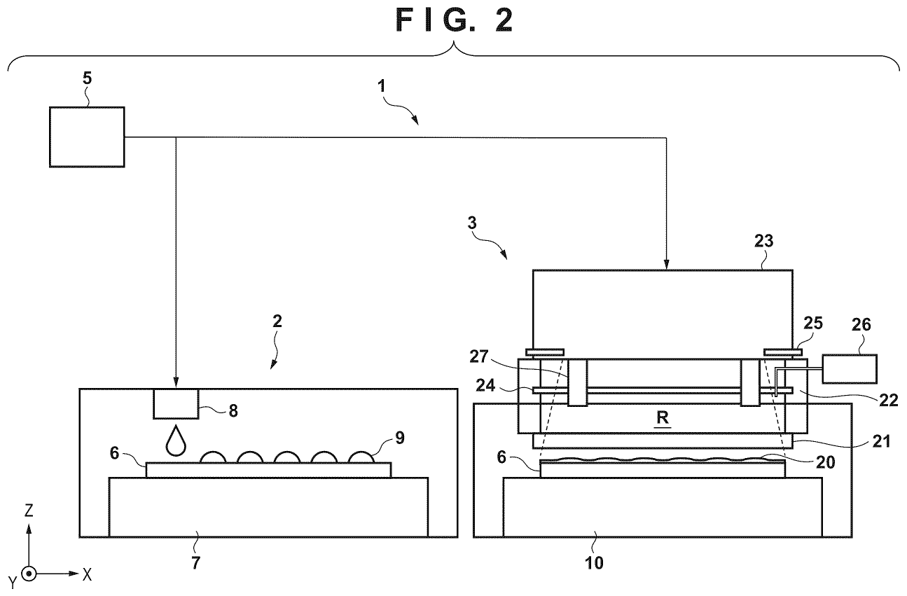

FIG. 2 is a schematic view showing the configuration of a film formation apparatus 1 according to this embodiment. In the accompanying drawings, the Z-axis is set along the vertical direction, and X- and Y-axes orthogonal to each other are set in a plane orthogonal to the Z-axis. Hereinafter, directions parallel to the X-, Y-, and Z-axes will be referred to as the X direction, the Y direction, and the Z direction, respectively.

Referring to FIG. 2, the film formation apparatus 1 can include a composition supply unit 2, a film formation unit 3, and a controller 5. A substrate 6 is conveyed to each of the composition supply unit 2 and the film formation unit 3 by a conveyance apparatus (not shown). The composition supply unit 2 includes a substrate stage 7 that is a substrate holder configured to hold the substrate and moves. The film formation unit 3 also includes a substrate stage 10 that is a substrate holder, like the substrate stage 7. A chuck (a vacuum chuck or an electrostatic chuck) (not shown) is mounted on the upper portion of each of the substrate stages 7 and 10, and the substrate 6 can be fixed by the chuck.

The composition supply unit 2 includes the substrate stage 7 that holds the substrate 6 (wafer) and moves, and a supply unit 8 (dispenser) that arranges a composition in a state of droplets on the substrate 6. The controller 5 can arrange a composition 9 containing a solvent and a polymerizable material on the substrate 6 using the supply unit 8 while relatively moving the substrate stage 7 and the supply unit 8 in the X and Y directions. A method of supplying droplets using the dispenser is called a jetting method, but another method (a spin coating method, a slit coating method, a screen printing method) may be employed.

The composition is a curable composition that is cured by receiving curing energy. As the curing energy, an electromagnetic wave, heat, or the like can be used. The electromagnetic wave can be, for example, light whose wavelength is selected from the range of 10 nm or more to 1 mm or less, for example, infrared rays, visible light, ultraviolet rays, and the like. The curable composition can be a composition to be cured by light irradiation or heating. Of these, a photocurable composition that is cured by light irradiation contains at least a polymerizable compound and a photopolymerization initiator, and may further contain a nonpolymerizable compound or a solvent, as needed. The nonpolymerizable compound is at least one type of material selected from the group consisting of a sensitizer, a hydrogen donor, an internal mold release agent, a surfactant, an antioxidant, a polymer component, and the like. The viscosity (the viscosity at 25° C.) of the curable composition can be, for example, 1 mPa·s or more to 100 mPa·s or less. As the material of the substrate, for example, glass, ceramic, a metal, a semiconductor, a resin, or the like can be used. A member made of a material different from that of the substrate may be provided on the surface of the substrate, as needed. The substrate 6 is, for example, a silicon wafer, a semiconductor compound wafer, or silica glass.

A representative base material of the substrate 6 is a silicon wafer, but the present disclosure is not limited to this. The substrate 6 can freely be selected from those known as semiconductor device substrates such as aluminum, a titanium-tungsten alloy, an aluminum-silicon alloy, an aluminum-copper-silicon alloy, silicon oxide, and silicon nitride. Note that as the substrate 6, a substrate on which an adhesion layer is formed by a surface treatment such as a silane coupling treatment, a silazane treatment, or deposition of an organic thin film to improve the adhesion to the curable material may be used. Note that the substrate 6 typically has a circular shape with a diameter of 300 mm, but the present disclosure is not limited to this.

In this embodiment, the composition 9 is a curable composition having such a characteristic to be cured by irradiation of light of a specific wavelength. The curable composition contains at least a polymerizable compound that is a nonvolatile component and a solvent that is a volatile component. The solvent is a solvent that dissolves the polymerizable compound. Examples of the solvent are an alcohol-based solvent, a ketone-based solvent, an ether-based solvent, an ester-based solvent, and a nitrogen-containing solvent. Also, in this specification, a cured film means a film formed by polymerizing the composition 9 on the substrate and curing it.

The film formation unit 3 includes the substrate stage 10 that holds the substrate 6 and moves, a mold holder 22 that holds a mold 21 (also called a superstrate or a planarization plate) to be brought into contact with a film 20 (liquid film) made of the composition 9 on the substrate 6, and an irradiator 23 that emits light to cure the liquid film 20. The irradiator 23 can include a light source. The light source can be formed by a UV lamp or a UV-LED. It is not limited to a specific light source if the light source emits light that passes through the mold 21 and has a wavelength for curing the composition 9. The mold 21 is made of a material that passes light emitted from the irradiator 23. The mold holder 22 sucks and holds the mold 21. In a state in which the mold 21 (the flat surface of the mold 21) is in contact with the liquid film 20 on the substrate 6, the irradiator 23 emits light to cure the liquid film 20 on the substrate 6, thereby forming a cured film (planarized film).

As the mold 21, a mold made of a light transmitting material is preferably used in consideration of the light irradiation step. As the type of the material forming the mold, more specifically, glass, quartz, a light transmitting resin such as polymethyl methacrylate (PMMA) or polycarbonate resin, a transparent metal deposition film, a soft film such as polydimethylsiloxane, a photocured film, a metal film, or the like is preferable. Note that the mold 21 preferably has a circular shape having a diameter larger than 300 mm and smaller than 500 mm, but the present disclosure is not limited to this. As will be described later with reference to FIG. 6B, the mold 21 can have a circular region 61 in which a planarized film should be formed (which should be brought into contact with a film on the substrate). Preferably, the diameter of the circular region 61 of the mold 21 can be 100 to 400 mm. Also, preferably, the diameter of the circular region 61 of the mold 21 can be 0.5 times or more and 1.5 times or less with respect to the diameter of the substrate 6. Also, the thickness of the mold 21 is preferably 0.25 mm or more and less than 2 mm, but the present disclosure is not limited to this.

A light transmitting member 24 is arranged above the mold 21. The mold 21, the mold holder 22, and the light transmitting member 24 form a closed space R. The pressure in the closed space R can be regulated by a pressure regulator 26. For example, when bringing the mold 21 into contact with the liquid film 20 on the substrate 6, the pressure regulator 26 sets the pressure in the closed space R higher than the outside, thereby deflecting the mold 21 such that it projects downward toward the substrate 6. Thus, contact (liquid contact) to the liquid film 20 starts from the center portion of the mold 21. After that, when the pressure in the closed space R is gradually lowered, the contact progresses from the center portion of the mold 21 to the peripheral portion. This prevents a gas from being confined between the mold 21 and the liquid film 20.

The film formation unit 3 further includes a shutter 25 configured to control the light irradiation range to the liquid film 20 on the substrate 6. The operation of the shutter 25 is controlled by a driving mechanism (not shown).

The film formation unit 3 can further include a TTM measurement unit 27. The TTM measurement unit 27 includes a scope that includes an optical system and an image capturing system and is configured to measure the position deviation amount between an alignment mark (substrate-side mark) arranged on the substrate 6 and an alignment mark (mold-side mark) arranged on the mold 21. Note that “TTM” is a short for “Through The Mold”, and it is intended to observe the mark on the mold side and the mark on the substrate side through the mold.

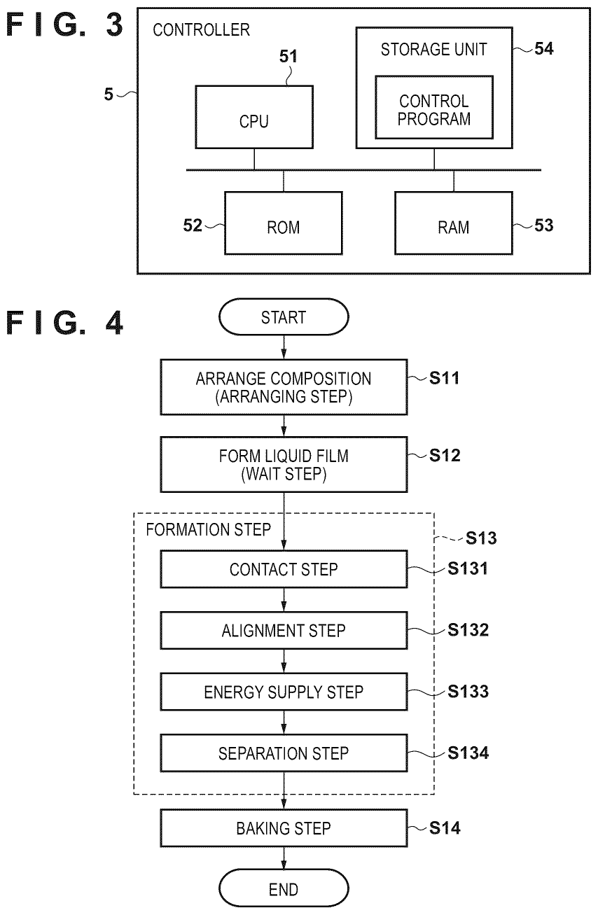

The controller 5 can control the overall film formation apparatus 1. More specifically, the controller 5 controls the conveyance apparatus (not shown), the supply unit 8, the irradiator 23, the mold holder 22, the pressure regulator 26, and the substrate stages 7 and 10. The controller 5 can be formed by a general-purpose or dedicated computer with programs installed therein or a combination of some or all of these. FIG. 3 shows an example of the configuration of the controller 5. The controller 5 shown in FIG. 3 is formed by a computer (information processing apparatus). The controller 5 can include, for example, a CPU 51, a ROM 52 that holds a boot program and permanent data, and a RAM 53 that provides the work area of the CPU 51 and holds temporary data. Also, the controller 5 can include a storage unit 54 including a control program configured to perform planarization processing.

A general film formation method by the film formation apparatus 1 will be described with reference to the flowchart of FIG. 4. Step S11 is an arranging step of arranging the composition 9 on the substrate 6. The substrate 6 loaded into the composition supply unit 2 by the conveyance apparatus is placed on the substrate stage 7 and fixed by the chuck. The controller 5 controls the supply unit 8 and the substrate stage 7, thereby discretely arranging the composition 9 on the substrate 6.

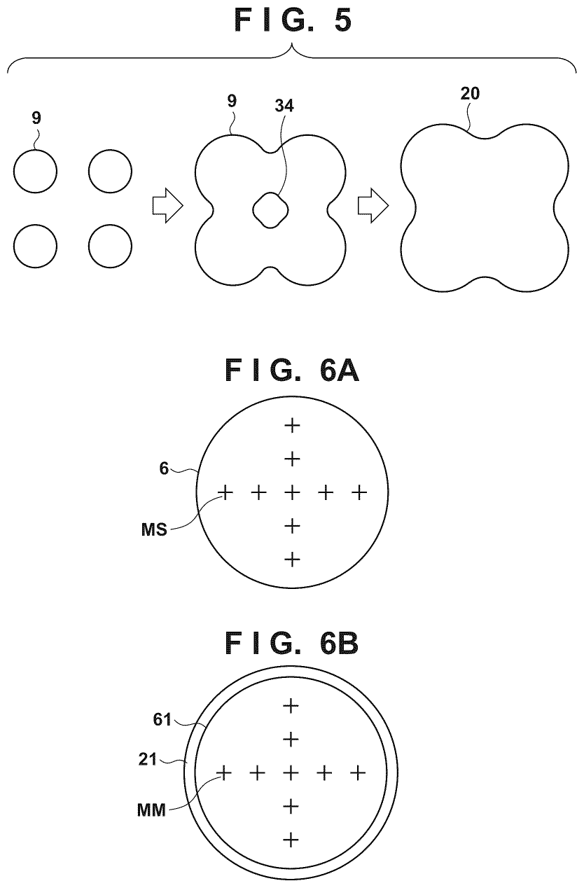

The substrate 6 with the composition 9 arranged thereon is unloaded from the composition supply unit 2 by the conveyance apparatus and loaded into the film formation unit 3. A plurality of droplets of the composition 9 discretely arranged on the substrate 6 by the supply unit 8 start spreading on the surface of the substrate 6 immediately after these are arranged on the substrate 6. FIG. 5 is a view showing the spread of the plurality of droplets of the composition 9 on the surface of the substrate 6. First, the plurality of discretely arranged droplets of the composition 9 start spreading on the substrate 6. As the spread of the plurality of droplets of the composition 9 progresses, adjacent droplets are combined and, finally, an inter-composition gap 34 (inter-droplet gap) is filled to form the liquid film 20. The liquid film formation state by the composition 9 may be observed using an image capturing unit (not shown).

Step S12 is a volatilization step of volatilizing the solvent contained in the liquid film. The volatilization step may be understood as a wait step of waiting for a predetermined time to volatilize the solvent contained in the liquid film. During the wait, environment adjustment for increasing the solvent volatilization effect may be performed.

Step S13 is a formation step of forming a cured film by curing the liquid film 20 formed on the substrate 6. The formation step can include a contact step S131, an alignment step S132, an energy supply step S133, and a separation step S134. In the contact step S131, the controller 5 drives at least one of the mold holder 22 and the substrate stage 10, thereby bringing the liquid film 20 on the substrate 6 and (the flat portion of) the mold 21 into contact with each other. In the alignment step S132, alignment between the substrate 6 and the mold 21 is performed in a state in which the liquid film 20 (composition) and the mold 21 are in contact. In the energy supply step S133, in a state in which the liquid film 20 and the mold 21 are in contact, the controller 5 causes the irradiator 23 to emit light as curing energy to cure the liquid film 20. Thus, a cured film (solid layer) is formed on the substrate 6. In the separation step S134, the controller 5 drives at least one of the mold holder 22 and the substrate stage 10, thereby separating the cured film 20 and the mold 21 from each other.

After that, in step S14, a baking step of heating the substrate 6 and the cured film on it can be performed. For example, the substrate 6 with the cured film of the composition 9 formed thereon is unloaded from the film formation unit 3 by the conveyance apparatus and loaded into a baking unit (not shown), and the baking step is performed.

FIGS. 6A and 6B show examples of the arrangements of alignment marks. FIG. 6A shows an example of substrate-side marks MS that are alignment marks arranged on the substrate 6. For example, the substrate-side marks MS can include an alignment mark arranged at the center of the substrate and alignment marks arranged at positions along a first direction and a second direction, which intersect each other at the center of the substrate. FIG. 6B shows an example of mold-side marks MM that are alignment marks arranged on the mold 21. The mold-side marks MM are arranged at positions corresponding to the substrate-side marks MS in the circular region 61 where the planarized film should be formed. That is, the mold-side marks MM can include an alignment mark arranged at the center of the circular region 61 and alignment marks arranged at positions along the first direction and the second direction, which intersect each other at the center of the circular region 61.

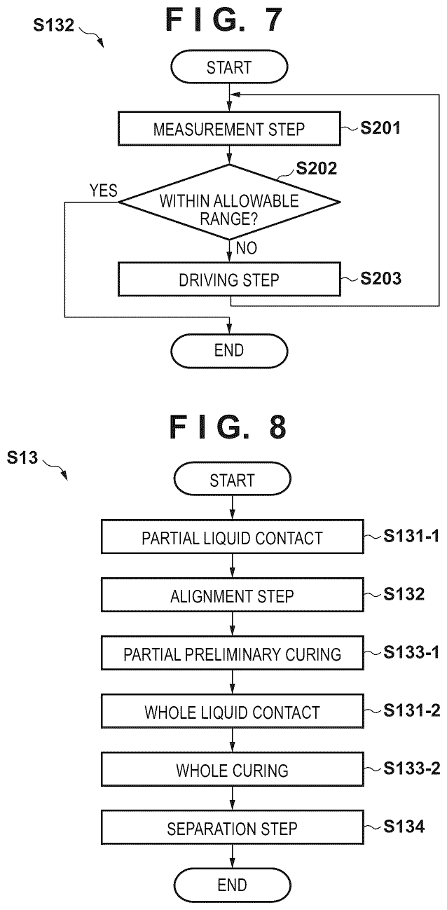

FIG. 7 is a flowchart of the alignment step S132. In a state in which at least a part of the mold 21 is in contact with the composition (liquid film 20) on the substrate by the contact step S131, in step S201, the controller 5 simultaneously observes the substrate-side marks MS and the mold-side marks MM using the TTM measurement unit 27, and measures a position deviation amount between these (measurement step). In step S202, the controller 5 determines whether the position deviation amount obtained in step S201 falls within an allowable range. If the position deviation amount falls within the allowable range, the alignment step is completed. If the position deviation amount does not fall within the allowable range, the process advances to step S203. In step S203, the controller 5 relatively drives the substrate stage 10 holding the substrate 6 and the mold holder 22 based on the position deviation amount (such that the position deviation amount becomes small) (driving step). The direction of driving can include a translation direction parallel to the substrate surface and a rotation direction about an axis extending in a direction perpendicular to the substrate surface. After that, the process returns to step S201.

FIG. 8 is a flowchart showing a detailed example of the formation step S13 according to this embodiment. FIGS. 9A to 9E are views showing the operation of the film formation unit 3 in the formation step S13. FIG. 9A shows a state in which the liquid film 20 is formed on the substrate 6 in step S12. In a first contact step S131-1, the controller 5 brings only a partial region of the mold 21 into contact with the liquid film 20 (partial liquid contact). For example, the pressure in the closed space R can be controlled by the pressure regulator 26 such that the partial region including the center of the mold 21 expands and projects downward toward the substrate 6. After that, the position of the mold 21 is adjusted by the mold holder 22 such that the liquid film 20 on the substrate 6 and the partial region including the center of the mold 21 contact each other.

After a part of the mold 21 contacts the liquid film 20, the controller 5 starts the alignment step S132 concerning the partial region before the entire surface of the circular region 61 of the mold 21 contacts the liquid film 20. The alignment step S132 concerning the partial region is performed by simultaneously observing, using the TTM measurement unit 27, the mold-side mark MM arranged at the center of the circular region 61 of the mold 21 and the substrate-side mark MS corresponding to it, as shown in FIG. 9B.

After completion of the alignment step S132, a first energy supply step S133-1 is executed. In step S133-1, the controller 5 executes the energy supply step concerning the partial region. More specifically, the controller 5 controls the shutter 25 and causes the irradiator 23 to emit light such that only the partial region is irradiated with the light from the irradiator 23, as shown in FIG. 9C. At this time, instead of completely curing the liquid film 20, preliminary curing of the liquid film in the partial region suffices such that the viscoelasticity of the liquid film 20 increases.

After that, the controller 5 makes the contact step progress. For example, in a second contact step S131-2, the controller 5 brings a peripheral region around the partial region of the mold 21 into contact with the liquid film 20. In an example, in the second contact step S131-2, the entire surface of the circular region 61 of the mold 21 is brought into contact with the liquid film 20 (whole liquid contact). More specifically, for example, the pressure in the closed space R can be controlled by the pressure regulator 26 such that the expansion of the mold 21 projecting downward becomes small. In parallel to this, the position of the mold 21 is adjusted by the mold holder 22 such that the liquid film 20 on the substrate 6 and the entire surface of the circular region 61 of the mold 21 contact each other. FIG. 9D shows a state in which the liquid film 20 on the substrate 6 and the entire surface of the circular region 61 of the mold 21 are in contact. Next, a second energy supply step S133-2 is executed. In step S133-2, the controller 5 executes the energy supply step concerning the partial region and the peripheral region (for example, the entire surface of the circular region 61). More specifically, the controller 5 controls the shutter 25 and causes the irradiator 23 to emit light such that the entire surface of the circular region 61 is irradiated with the light from the irradiator 23, as shown in FIG. 9E. The entire liquid film 20 is thus cured.

After that, the controller 5 executes the separation step S134.

As described above, in this embodiment, after a part of the mold 21 contacts the liquid film 20 in the contact step, the alignment step (S132) is started before the entire surface of the circular region 61 of the mold 21 contacts the liquid film 20. After that, partial preliminary curing (S133-1) of the liquid film 20 is performed and, therefore, the alignment accuracy of the mold 21 improves.

### Second Embodiment

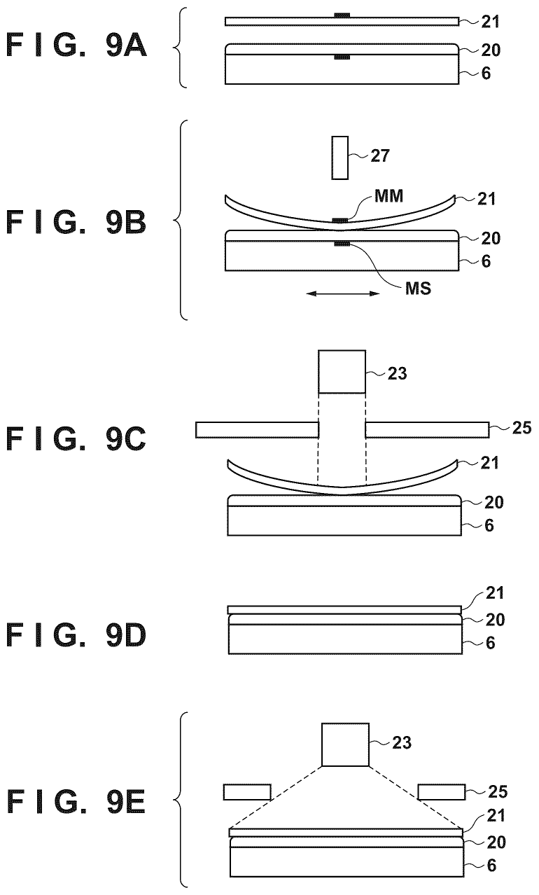

FIGS. 10A to 10E are views showing the operation of a film formation unit 3 in a formation step S13 according to the second embodiment. A difference from FIGS. 9A to 9E is FIG. 10B. As shown in FIG. 10B, a substrate stage 10 includes a heating unit H capable of partially applying heat to a substrate 6.

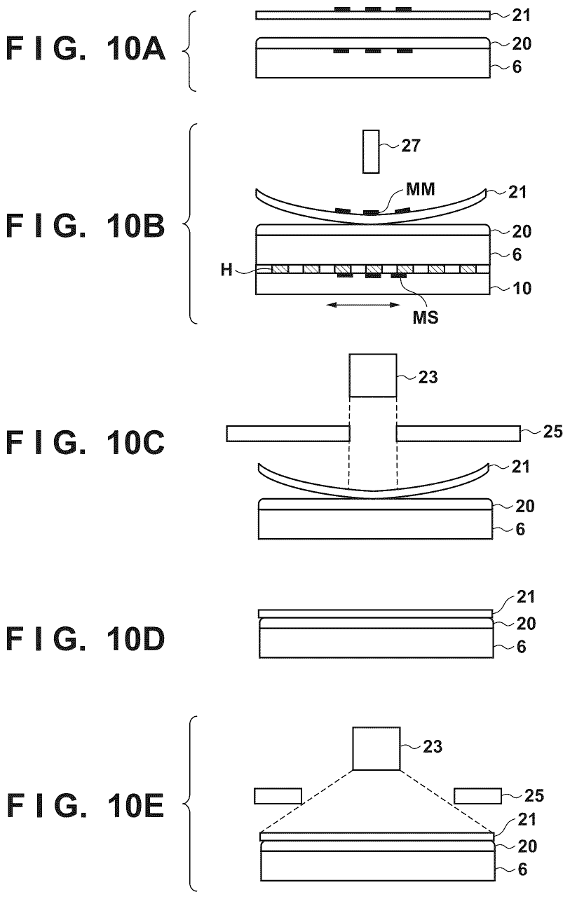

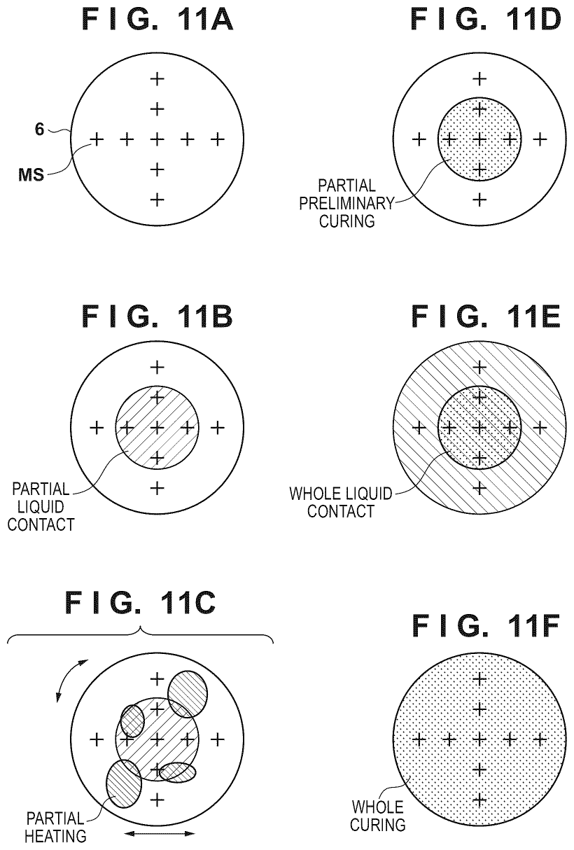

FIGS. 11A to 11F are views showing state transition on the substrate 6 in the formation step S13 according to the second embodiment. FIG. 11A is a plan view of the substrate 6, like FIG. 6A, and substrate-side marks MS are arranged in a cross. This shows a state before a contact step (FIG. 10A), and a liquid film 20 is not illustrated.

FIGS. 11B and 11C correspond to the state shown in FIG. 10B and show a state in which only the partial region of a mold 21 is in contact with the liquid film 20 (partial liquid contact) in a first contact step S131-1. In this state, a controller 5 starts an alignment step S132. The alignment step S132 is performed by simultaneously observing, using a TTM measurement unit 27, a mold-side mark MM arranged at the center of a circular region 61 of the mold 21 and the substrate-side mark MS corresponding to it. The alignment step S132 according to this embodiment can include measuring a plurality of mold-side marks MM arranged at the center of the circular region 61 of the mold 21 and around it and a plurality of substrate-side marks MS corresponding to these and obtaining a position deviation amount for each mark. The controller 5 calculates the distortion correction amount of the substrate 6 based on the position deviation amount of each mark. The controller 5 controls the heating unit H based on the distortion correction amount so as to partially apply heat to the substrate 6. The substrate 6 is thus deformed in high order, and the distortion can be corrected.

FIG. 11D corresponds to FIG. 10C and shows a state in which partial preliminary curing is performed in step S133-1. FIG. 11E corresponds to FIG. 10D and shows a state in which whole liquid contact is performed in step S131-2. FIG. 11F corresponds to FIG. 10E and shows a state in which whole curing is performed in step S133-2.

According to the second embodiment, since the alignment step further includes a deformation step of deforming the substrate 6 by partially applying heat to the substrate 6 based on the position deviation amount, the alignment accuracy can further be improved.

### Third Embodiment

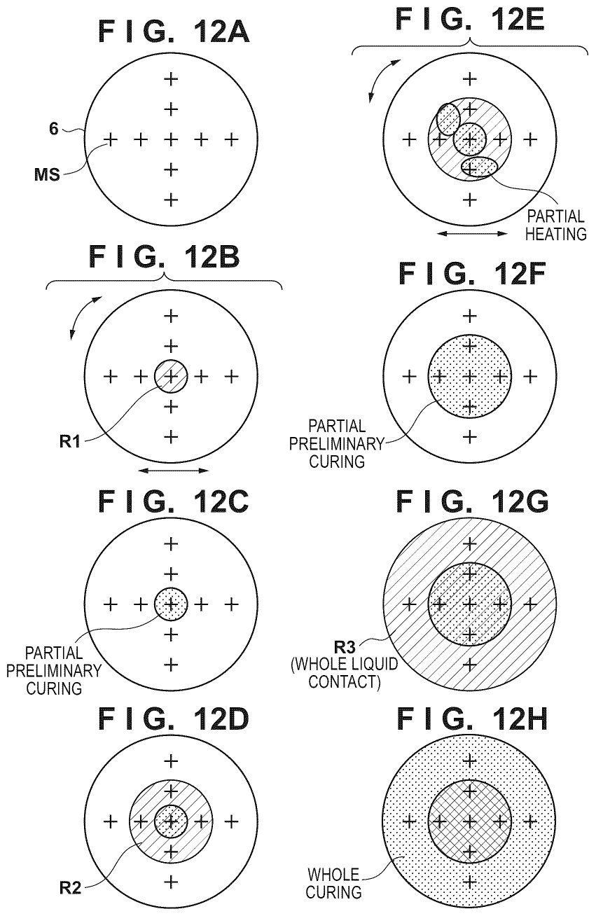

In a formation step S13, partial preliminary curing until whole curing is performed may be performed in a larger number of stages. FIGS. 12A to 12H are views showing state transition on a substrate 6 in the formation step S13 according to the third embodiment. FIG. 12A is a plan view of the substrate 6, like FIG. 6A, and substrate-side marks MS are arranged in a cross. This shows a state before a contact step (FIG. 10A), and a liquid film 20 is not illustrated.

FIG. 12B shows a state in which only a partial region R1 of a mold 21 is in contact with the liquid film 20 (partial liquid contact) as a first contact step. In this state, a controller 5 starts an alignment step S132. The alignment step S132 is performed by simultaneously observing, using a TTM measurement unit 27, a mold-side mark MM arranged at the center of a circular region 61 of the mold 21 and the substrate-side mark MS corresponding to it. After that, partial preliminary curing is executed for the partial region R1, as shown in FIG. 12C.

FIG. 12D shows a state in which the contact step is made to progress and a first peripheral region R2 around the partial region R1 is in contact with the liquid film 20. In this state, the controller 5 executes the alignment step using a plurality of mold-side marks MM inside the first peripheral region R2 and a plurality of substrate-side marks MS corresponding to these. At this time, as shown in FIG. 12E, distortion correction may be performed by partially heating the substrate 6 using a heating unit H, like the second embodiment (FIG. 11C).

FIG. 12F shows a state in which partial preliminary curing for the first peripheral region R2 is performed. FIG. 12G shows a state in which the contact step is made to further progress and even a second peripheral region R3 around the first peripheral region is in contact with the liquid film 20. The second peripheral region R3 can be the entire surface of the circular region 61 of the mold 21, as shown in FIG. 12G. FIG. 12H shows a state in which curing (for example, whole curing) up to the second peripheral region R3 is performed.

In this way, partial preliminary curing until whole curing is performed is in a larger number of stages, and the alignment accuracy can further be improved.

### Fourth Embodiment

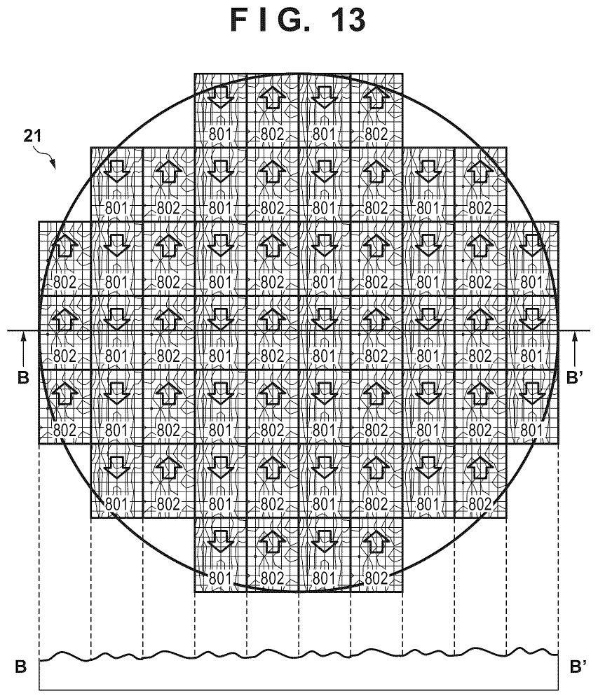

As a mold 21, a mold having a surface shape according to the image plane shape of an exposure apparatus used to form a resist pattern on a planarized film can be used. FIG. 13 schematically shows a plan view and a sectional view of the mold 21. For the mold 21, the scanning direction of each shot region in a scanning exposure apparatus configured to perform exposure processing for a substrate with a planarized film formed thereon may be taken into consideration. In the scanning exposure apparatus, the image plane shape may change in accordance with the scanning direction. Hence, the mold 21 can be manufactured using a relief stamp according to down scan 801 that scans the substrate in the down direction and up scan 802 that scans the substrate in the up direction. That is, the mold 21 having a surface shape according to the scanning direction can be manufactured. It is useful to arrange alignment marks (mold-side marks MM) described above on the mold 21. The mold 21 may be manufactured by, for example, a plurality of photolithography steps. The thus formed mold 21 may be provided with a protective film to protect its surface. The protective film can be formed by, for example, coating the surface of the mold 21 with Cytop®.

### Embodiment of Article Manufacturing Method

A method of manufacturing articles (a semiconductor IC element, a liquid crystal display element, a color filter, a MEMS, and the like) using the above-described molding apparatus will be described next. The article manufacturing method includes a step of planarizing a composition arranged on a substrate (a wafer, a glass substrate, or the like) using a film formation apparatus as the above-described molding apparatus, and a step of curing the composition. A planarized film is thus formed on the substrate. Processing of forming a pattern using a lithography apparatus is performed for the substrate with the planarized film formed thereon, and the processed substrate is processed by other known processing steps, thereby manufacturing an article. The other known steps include patterning exposure and preprocessing associated with this, etching, resist removal, dicing, bonding, packaging, and the like. According to the manufacturing method, it is possible to manufacture an article of higher quality than before.

According to the above-described various embodiments, it is possible to provide a technique advantageous in improving the alignment accuracy of a mold used to form a planarized film.

### Other Embodiments

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (dvd), or Blu-ray Disc (BD)™), a flash memory device, a memory card, and the like.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-143356, filed Aug. 23, 2024 which is hereby incorporated by reference herein in its entirety.

What is claimed is:

1. A film formation method of forming a planarized film on a substrate, comprising:
bringing a circular region of a mold, in which the planarized film should be formed, into contact with a composition on the substrate;
performing alignment between the substrate and the mold in a state in which the composition and the mold are in contact; and
applying curing energy to the composition after the performing alignment,
wherein after a part of the mold contacts the composition in the bringing the mold into contact with the composition, the performing alignment is started before an entire surface of the circular region of the mold contacts the composition.

2. The method according to claim 1, wherein
the performing alignment includes:
measuring a position deviation amount between a substrate-side mark arranged on the substrate and a mold-side mark arranged on the mold; and
relatively driving a substrate holder that holds the substrate and a mold holder that holds the mold based on the position deviation amount.

3. The method according to claim 2, wherein
in a state in which only a partial region of the mold is brought into contact with the composition in the bringing the mold into contact with the composition, the performing alignment and the applying curing energy are executed concerning the partial region, and
after that, in a state in which the bringing the mold into contact with the composition is made to progress to bring a peripheral region around the partial region of the mold into contact with the composition, the applying curing energy is executed concerning the partial region and the peripheral region.

4. The method according to claim 2, wherein
in a state in which only a partial region of the mold is brought into contact with the composition in the bringing the mold into contact with the composition, the performing alignment and the applying curing energy are executed concerning the partial region,
after that, in a state in which the bringing the mold into contact with the composition is made to progress to bring a first peripheral region around the partial region of the mold into contact with the composition, the applying curing energy is executed concerning the partial region and the first peripheral region, and
after that, in a state in which the bringing the mold into contact with the composition is made to further progress to bring the partial region of the mold, the first peripheral region, and a second peripheral region around the first peripheral region into contact with the composition, the applying curing energy is executed concerning the partial region, the first peripheral region, and the second peripheral region.

5. The method according to claim 3, wherein the performing alignment further includes deforming the substrate by partially applying heat to the substrate based on the position deviation amount.

6. The method according to claim 3, wherein the partial region is a region including a center of the mold.

7. The method according to claim 1, wherein a diameter of the circular region of the mold is 100 to 400 mm.

8. The method according to claim 1, wherein a diameter of the circular region of the mold is not less than 0.5 times and not more than 1.5 times with respect to a diameter of the substrate.

9. The method according to claim 1, wherein as the mold, a mold having a surface shape according to an image plane shape of an exposure apparatus used to form a resist pattern on the planarized film is used.

10. An article manufacturing method comprising:
forming a film of a composition on a substrate in accordance with a film formation method defined in claim 1; and
processing the substrate with the film formed in the forming,
wherein an article is manufactured from the processed substrate.
